(19) United States
(12) Patent Application Publication
(10) Pub. No.: US 2026/0185382 A1
(43) Pub. Date: Jul. 2, 2026

(54) ELECTRIC LOCK AND CABLE ARRANGEMENT STRUCTURE THEREOF

(71) Applicant: Taiwan Fu Hsing Industrial Co., Ltd., Kaohsiung City (TW)

(72) Inventor: Yi-Fang Huang, Kaohsiung City (TW)

(73) Assignee: Taiwan Fu Hsing Industrial Co., Ltd., Kaohsiung City (TW)

(21) Appl. No.: 19/056,778

(22) Filed: Feb. 19, 2025

(30) Foreign Application Priority Data
Jan. 2, 2025 (TW) 114100007

(51) Int. Cl. E05B 9/08; E05B 47/00; H05K 5/02

(52) U.S. Cl. CPC E05B 9/08; E05B 47/0001; H05K 5/0247

(57) ABSTRACT

An electric lock includes an inner lock body, an outer lock body, a connection cable, and a cable arrangement structure. The inner lock body and the outer lock body are disposed oppositely. The connection cable extends from the inner lock body to the outer lock body. The cable arrangement structure is disposed between the inner lock body and the outer lock body and includes a cable-accommodating portion and a structural fixing portion connected to the cable-accommodating portion. The cable-accommodating portion has a cable channel. The cable arrangement structure is fixed to the inner lock body or the outer lock body through the structural fixing portion. The connection cable passes through and is fixed in the cable channel.

### BACKGROUND OF THE INVENTION

### 1. Field of the Invention

The present invention relates to an electric lock, and more particularly to an electric lock with a cable arrangement structure and the cable arrangement structure.

### 2. Description of the Prior Art

The inner lock body and outer lock body of an electric lock are usually equipped with electronic components. In order to enable communication or power transmission between these electronic components, a connection cable is usually used to connect the inner lock body and the outer lock body. However, there are still many movable parts in the electric lock (for example, located in the inner lock body, the outer lock body, or between the inner lock body and the outer lock body). If the connection cable that is not effectively fixed, it will easily interfere with these movable parts, causing abnormal movement of the movable part and possibly damaging the connection cable.

### SUMMARY OF THE INVENTION

In view of the problems in the prior art, an objective of the invention is to provide a cable arrangement structure, used in an electric lock. The cable arrangement structure can effectively fix a connection cable connecting two lock bodies in the electric lock.

A cable arrangement structure of an embodiment according to the invention is used in an electric lock. The electric lock includes an inner lock body, an outer lock body, and a connection cable. the connection cable extend from the inner lock body to the outer lock body. The cable arrangement structure includes a cable-accommodating portion and a structural fixing portion. The cable-accommodating portion has a cable channel. The structural fixing portion is connected to the cable-accommodating portion. Therein, the cable arrangement structure is fixed to the inner lock body or the outer lock body through the structural fixing portion. The connection cable passes through and is fixed in the cable channel. Thereby, the cable arrangement structure can effectively fix the connection cable and prevent the connection cable from interfering with other movable components in the electric lock.

Another objective of the invention is to provide an electric lock, which uses the above-mentioned cable arrangement structure to fix a connection cable, thereby preventing the connection cable from interfering with other movable components in the electric lock.

An electric lock of an embodiment according to the invention includes an inner lock body, an outer lock body, a connection cable and a connection cable. The inner lock body and the outer lock body are disposed oppositely. The connection cable extends from the inner lock body to the outer lock body. The cable arrangement structure includes a cable-accommodating portion and a structural fixing portion. The cable-accommodating portion has a cable channel. The structural fixing portion is connected to the cable-accommodating portion. The cable arrangement structure is disposed between the inner lock body and the outer lock body and is fixed to the inner lock or the outer lock through the structural fixing portion. The connection cable passes through and is fixed in the cable channel. Thereby, the position of the connection cable between the inner lock body and the outer lock body is fixed. The positions where the connection cable enters the inner lock body and the outer lock body can also be restricted to avoid interference between the connection cable and other movable components in the electric lock.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating an electric lock according to an embodiment.

FIG. 2 is a partially-exploded view of the electric lock in FIG. 1.

FIG. 3 is another partially-exploded view of the electric lock in FIG. 1.

FIG. 4 is a schematic diagram illustrating a cable arrangement structure of the electric lock in FIG. 2 and FIG. 3.

FIG. 5 is a schematic diagram of the cable arrangement structure in FIG. 4 in another viewpoint.

FIG. 6 is a schematic diagram illustrating that the cable arrangement structure in FIG. 4 is fixed onto a base plate of an outer lock body of the electric lock.

### DETAILED DESCRIPTION

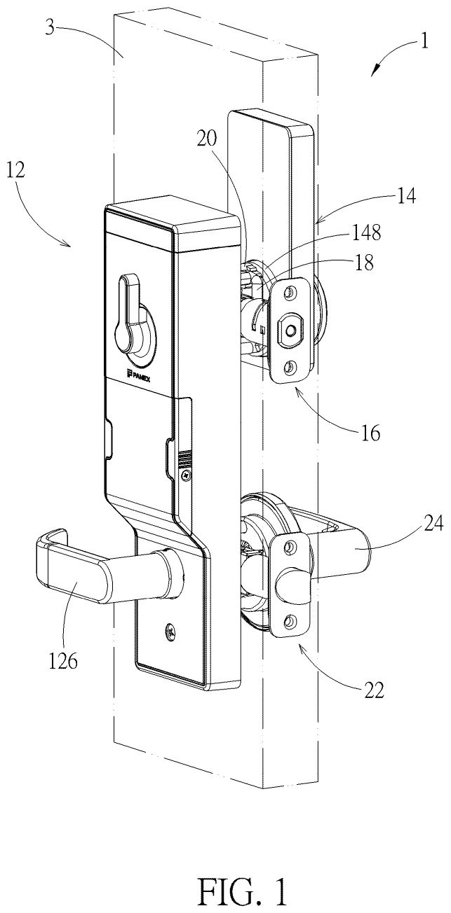

Please refer to FIG. 1 to FIG. 3. An electric lock 1 according to an embodiment includes an inner lock body 12, an outer lock body 14, a latch assembly 16, a connection cable 18 (e.g., but not limited to wire harnesses, flat cables, cables, etc.), and a cable arrangement structure 20. The electric lock 1 is installed onto a door panel 3 (simply shown in FIG. 1 with chain lines). The inner lock body 12 and the outer lock body 14 are disposed on opposite sides of the door panel 3 (i.e., inner and outer sides of the door panel 3), and the two are also fixedly connected through several connection posts (such as threaded hole posts 142) and screws screwed into the threaded hole posts 142. The latch assembly 16 is disposed between the inner lock body 12 and the outer lock body 14 and in an installation hole of the door panel 3. The latch assembly 16 is connected to the inner lock body 12 and the outer lock body 14 (through a latch drive lever 144), so that the inner lock body 12 and the outer lock body 14 can drive a latch of the latch assembly 16 through the latch drive lever 144. The connection cable 18 extends from the inner lock body 12 and the outer lock body 14 and is electrically connected to a circuit board assembly 122 in the inner lock body 12 and a circuit board assembly 146 in the outer lock body 14, so that the circuit board assembly 122 and the circuit board assembly 146 can communicate or transmit power through the connection cable 18. The cable arrangement structure 20 is fixedly disposed between the inner lock body 12 and the outer lock body 14 and fixes the connection cable 18, thereby avoiding interference between the connection cable 18 and other movable components of the electric lock 1. Furthermore, in practice, the connection cable 18 is not limited to be connected to circuit board assemblies, and can be connected to other electronic components (such as but not limited to batteries, motors, etc.).

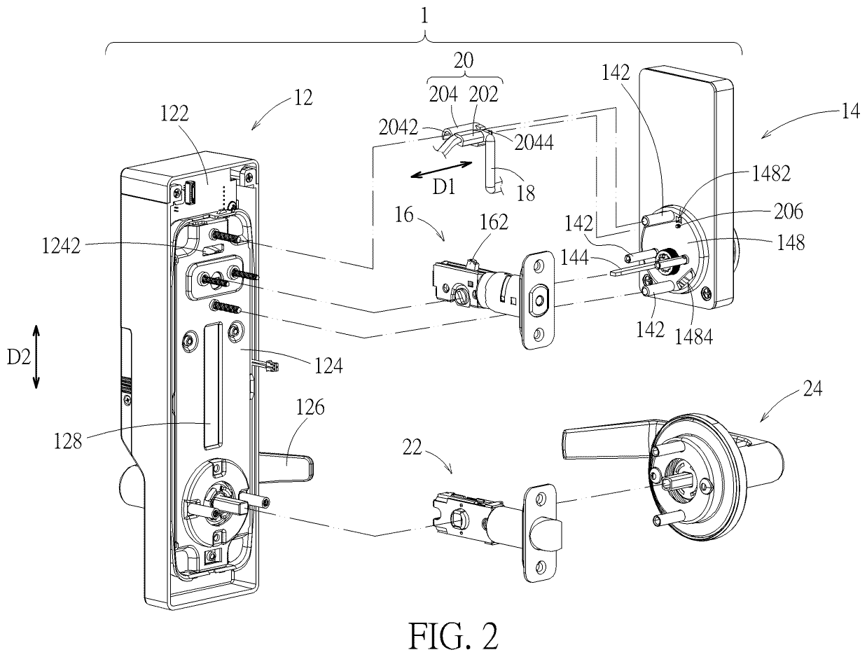

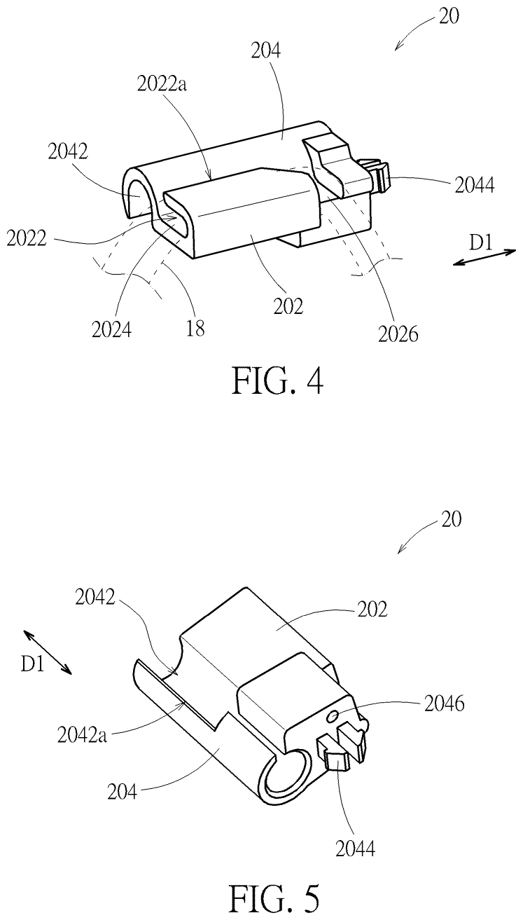

Please refer to FIG. 4 to FIG. 6. The cable arrangement structure 20 includes a cable-accommodating portion 202 and a structural fixing portion 204 that are connected. The cable-accommodating portion 202 has a cable channel 2022, a first entrance 2024, and a second entrance 2026. The cable channel 2022 extends along a direction D1 (indicated by a double-headed arrow in the figures). The first entrance 2024 and the second entrance 2026 are connected to opposite sides of the cable channel 2022, respectively. The first entrance 2024 is parallel to the direction D1, and the second entrance 2026 is non-parallel to the direction D1 (e.g., perpendicular to the direction D1). The cable arrangement structure 20 fixes the connection cable 18 through the cable-accommodating portion 202. Therein, the connection cable 18 (of which the outline is shown in dashed lines in FIG. 4; also referring to FIG. 2) passes through the first entrance 2024, the cable channel 2022, and the second entrance 2026, and is fixed in the cable channel 2022. The orientation of the first entrance 2024 is different from the orientation of the second entrance 2026, which is conducive to the fixation of the connection cable 18. Furthermore, in the embodiment, the cable channel 2022 has an open slot 2022a extending along the direction D1. From the viewpoint of FIG. 4, the open slot 2022a is facing upward. The open slot 2022a facilitates plugging the connection cable 18 into the cable channel 2022. In practice, the open slot 2022a is not limited to extending in a straight line, for example, extending in a wavy line. On the other hand, the cable channel 2022 has no downward open slot, so that the connection cable 18 itself will not fall off from the cable channel 2022 under the action of gravity. In addition, in the embodiment, the cross-section of the cable channel 2022 is slightly flat rectangular, which helps the cable arrangement structure 20 squeeze the connection cable 18 accommodated in the cable channel 2022 through the cable channel 2022 (e.g., slightly flattening the cable with a circular cross-section).

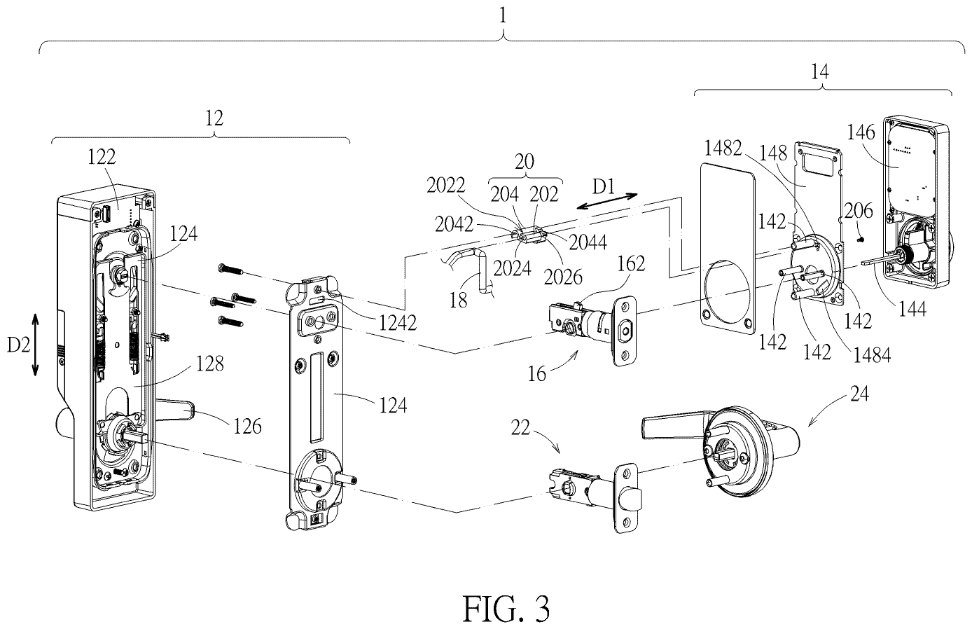

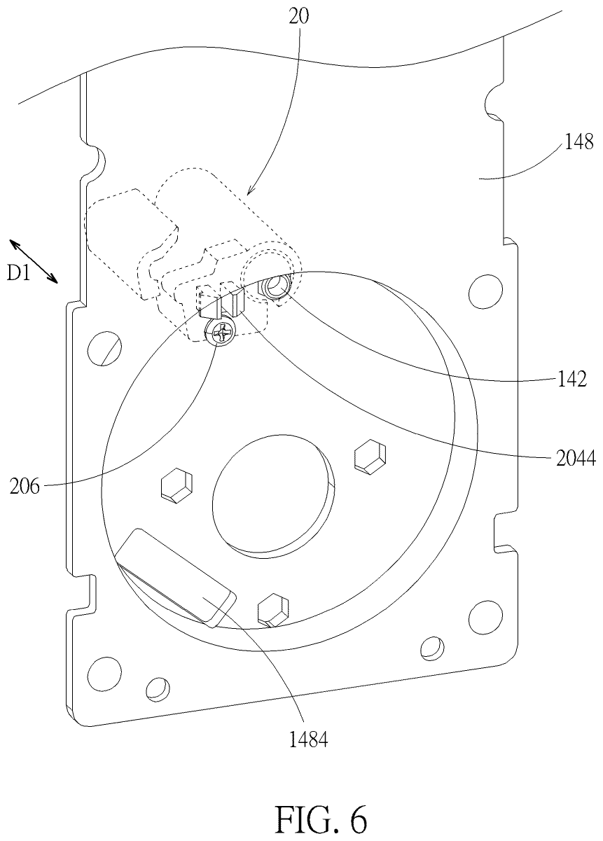

The structural fixing portion 204 includes a through hole 2042, an engagement structure 2044, and a threaded hole 2046. The through hole 2042 and the threaded hole 2046 both extend along the direction D1. The engagement structure 2044 protrudes along the direction D1 relative to the cable-accommodating portion 202 (or the cable channel 2022 thereof). The cable arrangement structure 20 is fixed between the inner lock body 12 and the outer lock body 14 through the structural fixing portion 204. Therein, one of the threaded hole posts 142 (fixed on a base plate 148 of the outer lock body 14) fits in the through hole 2042 (also referring to FIG. 1). The engagement structure 2044 engages with an engagement hole 1482 of the base plate 148. The threaded hole 2046 is fixed onto the base plate 148 through a screw 206 (as shown by FIG. 6, in which the hidden outline of the cable arrangement structure 20 is shown in dashed lines; also referring to FIG. 2 and FIG. 3). Therefore, in the embodiment, the cable arrangement structure 20 is directly fixed on the outer lock body 14 through the structural fixing portion 204. Moreover, logically, in principle, the through hole 2042, the engagement structure 2044, and the threaded hole 2046 (with the corresponding screw) can individually produce the effect of fixing the cable arrangement structure 20, so in practice, they can be implemented selectively. For example, the threaded hole post 142 and the through hole 2042 tightly fits. For another example, the corresponding screw is tightly screwed into the threaded hole 2046. For another example, the engagement hole 1482 is not circular and thus has a positioning effect (preventing the engagement structure 2044 from rotating relative to the engagement hole 1482). Furthermore, in the embodiment, the engagement structure 2044 is realized by a pair of elastic arms with protrusions. The elastic arms are inserted into the engagement hole 1482 and held on the base plate 148 through the protrusions. In addition, in the embodiment, the projections of the cable channel 2022 and the engagement structure 2044 in the direction D1 overlap. This structural configuration helps to reduce the impact of stress generated by the connection cable 18 on the engagement structure 2044 through the cable channel 2022 (e.g., reducing the torque exerted on the engagement structure 2044).

Furthermore, in the embodiment, the through hole 2042 has an open slot 2042a extending along the direction D1. From the viewpoint of FIG. 4, the open slot 2042a is facing downward. On the other hand, the through hole 2042 has no upward open slot, so that the arrangement structure 20 itself will not fall off from the threaded hole post 142 under the action of gravity. The existence of the open slot 2042a can make the hole structure (forming the through hole 2042) have a certain degree of elasticity, which helps to adapt to threaded hole posts 142 with different outer diameters, thereby increasing the applicability of the cable arrangement structure 20. In practice, the specific outline of the open slot 2042a can be designed according to an actual product structure, which will not be described in addition.

In addition, in the embodiment, in logic, the cable arrangement structure 20 can also be regarded as being indirectly fixed to the inner lock body 12 through the structural fixing portion 204 (i.e., through the threaded hole post 142, the corresponding screw, and the base plate 124 of the inner lock body 12 (therein, the screw is screwed on the base plate 124) to be fixed to the inner lock body 12). Moreover, in practice, the cable arrangement structure 20 can also be directly fixed on the inner lock body 12 instead, for example, by swapping the aforementioned structural configuration of fixing the connection cable 18 (including the cable arrangement structure 20, the engagement hole 1482 on the base plate 148, the through hole of the base plate 148 corresponding to the threaded hole 2046, and the threaded hole posts 142) back and forth along the direction D1.

Furthermore, in the embodiment, the structural fixing portion 204 is engaged to the threaded hole post 142 through the through hole 2042. Moreover, the through hole 2042 and the cable channel 2022 are adjacent and extend in parallel. The extension length of the through hole 2042 is greater than the extension length of the cable channel 2022. This structural configuration can enhance the supporting effect of the threaded hole post 142 on the cable arrangement structure 20, thereby increasing the stability of the cable arrangement structure 20 in supporting and fixing the connection cable 18. However, it is not limited thereto in practice. For example, the through hole 2042 is realized by at least one hook (arranged along the direction D1), and the cable arrangement structure 20 can still use the at least one hook to hook the threaded hole post 142 to obtain support.

Please refer to FIG. 1 to FIG. 3. In the embodiment, from the viewpoint of FIG. 1) the cable arrangement structure 20 is located on the upper side of the latch assembly 16 and is separate from the latch assembly 16. The connection cable 18 also bypasses the upper side of the latch assembly 16. Since the cable arrangement structure 20 can effectively fix the connection cable 18, the connection cable 18 can keep at least a small distance from the latch assembly 16 and will not interfere with the movable part of the latch assembly 16 (e.g., the link lever 162, which links the latch drive lever 144 and a latch head) and affect the action of the latch assembly 16. Furthermore, in the embodiment, the connection cable 18 enters the outer lock body 14 through an opening 1484 of the base plate 148 of the outer lock body 14, and also enters the inner lock body 12 through an opening 1242 of the base plate 124 of the inner lock body 12. In the embodiment, the electric lock 1 also includes another latch assembly 22 (under the latch assembly 16) and an outer handle 24. The inner lock body 12 also includes an inner handle 126. The latch assembly 22 is disposed in an installation hole of the door panel 3. The outer handle 24 and the inner handle 126 are connected to the latch assembly 22 to drive a latch of the latch assembly 22. Moreover, the inner lock body 12 also includes a movable part 128. The movable part 128 is movable along a moving direction D2 (indicated by a double-headed arrow in FIG. 2 and FIG. 3). The movable part 128 is linked with the inner handle 126. The latch assembly 16 limits the movement of the latch assembly 22 (through the inner handle 126) according to its status (e.g., locked or unlocked). The connection cable 18 is located on the upper side of movable part 128 along the moving direction D2 in the inner lock body 12 and is separate from the movable part 128, so the connection cable 18 will not interfere with the movable part 128 and affect the movement of the movable part 128.

In addition, in the embodiment, the cable arrangement structure 20 is a single structural component (for example, but not limited to, through one-piece molding); however, it is not limited thereto in practice.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A cable arrangement structure, used in an electric lock, the electric lock comprising an inner lock body, an outer lock body, and a connection cable, the connection cable extending from the inner lock body to the outer lock body, the cable arrangement structure comprising:
a cable-accommodating portion, the cable-accommodating portion having a cable channel; and
a structural fixing portion, the structural fixing portion being connected to the cable-accommodating portion;
wherein the cable arrangement structure is fixed to the inner lock body or the outer lock body through the structural fixing portion, and the connection cable passes through and is fixed in the cable channel.

2. The cable arrangement structure according to claim 1, wherein the cable channel extends along a direction, the structural fixing portion comprises a through hole, and the through hole extends along the direction.

3. The cable arrangement structure according to claim 2, wherein the cable channel has an open slot, the through hole has an open slot, the open slot of the cable channel and the open slot of the through hole both extend along the direction, and an orientation of the open slot of the cable channel is opposite to an orientation of the open slot of the through hole.

4. The cable arrangement structure according to claim 1, wherein the cable channel extends along a direction, the structural fixing portion comprises an engagement structure, and the engagement structure protrudes along the direction relative to the cable channel.

5. The cable arrangement structure according to claim 1, wherein the cable channel extends along a direction, the structural fixing portion comprises a threaded hole, and the threaded hole extends along the direction.

6. The cable arrangement structure according to claim 1, wherein the cable channel extends along a direction, the cable-accommodating portion has a first entrance and a second entrance, the first entrance and the second entrance are respectively connected to opposite sides of the cable channel, the first entrance is parallel to the direction, and the second entrance is non-parallel to the direction.

7. An electric lock, comprising:
an inner lock body;
an outer lock body, the inner lock body and the outer lock body being disposed oppositely;
a connection cable, the connection cable extending from the inner lock body to the outer lock body; and
a cable arrangement structure, the cable arrangement structure being disposed between the inner lock body and the outer lock body, the cable arrangement structure comprising:
a cable-accommodating portion, the cable-accommodating portion having a cable channel; and
a structural fixing portion, the structural fixing portion being connected to the cable-accommodating portion;
wherein the cable arrangement structure is fixed to the inner lock body or the outer lock body through the structural fixing portion, and the connection cable passes through and is fixed in the cable channel.

8. The electric lock according to claim 7, wherein the inner lock body or the outer lock body comprises a connection post, the inner lock body and the outer lock body are connected through the connection post, and the structural fixing portion is engaged to the connection post.

9. The electric lock according to claim 7, wherein the inner lock body or the outer lock body comprises a base plate, and the structural fixing portion is engaged to the base plate.

10. The electric lock according to claim 7, further comprising a latch assembly, wherein the latch assembly is disposed between the inner lock body and is connected to the inner lock body and the outer lock body, and the cable arrangement structure is located on one side of the latch assembly and is separate from the latch assembly.

11. The electric lock according to claim 7, wherein the inner lock body or the outer lock body comprises a movable part, the movable part is movable along a moving direction, and the connection cable is located on one side of the movable part in the inner lock body in the moving direction and is separate from the movable part.

12. The electric lock according to claim 7, wherein the cable channel extends along a direction, the structural fixing portion comprises a through hole, and the through hole extends along the direction.

13. The electric lock according to claim 12, wherein the cable channel has an open slot, the through hole has an open slot, the open slot of the cable channel and the open slot of the through hole both extend along the direction, and an orientation of the open slot of the cable channel is opposite to an orientation of the open slot of the through hole.

14. The electric lock according to claim 7, wherein the cable channel extends along a direction, the structural fixing portion comprises an engagement structure, and the engagement structure protrudes along the direction relative to the cable channel.

15. The electric lock according to claim 7, wherein the cable channel extends along a direction, the structural fixing portion comprises a threaded hole, and the threaded hole extends along the direction.

16. The electric lock according to claim 7, wherein the cable channel extends along a direction, the cable-accommodating portion has a first entrance and a second entrance, the first entrance and the second entrance are respectively connected to opposite sides of the cable channel, the first entrance is parallel to the direction, and the second entrance is non-parallel to the direction.
